(19) United States
(12) Patent Application Publication
(10) Pub. No.: US 2025/0212577 A1
(43) Pub. Date: Jun. 26, 2025

(54) DISPLAY APPARATUS AND MANUFACTURING METHOD OF THE SAME

(71) Applicant: LG Display Co., Ltd., Seoul (KR)

(72) Inventor: Sangmin PARK, Gimpo-si (KR)

(21) Appl. No.: 18/940,478

(22) Filed: Nov. 7, 2024

(30) Foreign Application Priority Data
Dec. 21, 2023 (KR) 10-2023-0188162

(51) Int. Cl. H01L 33/62; H01L 25/075; H01L 25/16; H01L 33/00

(52) U.S. Cl. CPC H10H 20/857; H01L 25/167; H01L 25/0753; H10H 20/01; H10H 20/0364

(57) ABSTRACT

Provided is a display apparatus. The display apparatus may comprises a substrate, a driving circuit unit disposed on the substrate in an active area, a first insulating layer disposed on the driving circuit unit, a second insulating layer which includes a convex portion while enclosing at least one end of the first insulating layer, a light emitting diode disposed on the convex portion of the second insulating layer, and a third insulating layer which includes a concave portion while enclosing an end of the first insulating layer or the second insulating layer, wherein the convex portion and the concave portion at least partially overlap.

### CROSS-REFERENCE TO RELATED APPLICATIONS

This application claims the priority and benefits of Korean Patent Application No. KR 10-2023-0188162 filed on Dec. 21, 2023, in the Korean Intellectual Property Office, the disclosure of which is incorporated herein in its entirety by reference for all purposes, as if full set forth herein.

### BACKGROUND

### Technical Field

The present disclosure relates to a display apparatus and a manufacturing method of the same, and more particularly, for example, without limitation, to a display apparatus using a light emitting diode (LED) and a manufacturing method of the same.

### Description of the Related Art

As display apparatuses which are used for a monitor of a computer, a television, or a cellular phone, there are an organic light emitting display (OLED) device which is a self-emitting device, a liquid crystal display (LCD) device which requires a separate light source, and the like.

An applicable range of the display apparatus is diversified to personal mobile devices as well as monitors of computers and televisions, and even vehicles, appliances and buildings, etc., and a display apparatus with a large display area and a reduced volume and weight is being studied.

Further, recently, a display apparatus including a light emitting diode (LED) is attracting attention as a next generation display apparatus. Since the LED is formed of an inorganic material, rather than an organic material, reliability is excellent so that a lifespan thereof is longer than that of the liquid crystal display apparatus or the organic light emitting display apparatus. Further, the LED has a fast lighting speed, excellent luminous efficiency, and a strong impact resistance so that a stability is excellent and an image having a high luminance can be displayed.

The description provided in the background section should not be assumed to be prior art merely because it is mentioned in or associated with the background section. The background section may include information that describes one or more aspects of the subject technology.

### BRIEF SUMMARY

Various embodiments of the present disclosure provide a display apparatus which improves a connection contact hole step of a light emitting diode and a power line and a driver below the light emitting diode by a plurality of insulating films and a manufacturing method of the same.

Various embodiments of the present disclosure provide a display apparatus which suppresses the short-circuit of a connection line and improves a reflectance of the display apparatus and a manufacturing method of the same.

According to an aspect of the present disclosure, there is provided a display apparatus. The display apparatus comprises a substrate, a driving circuit unit disposed on the substrate in an active area, a first insulating layer disposed on the driving circuit unit, a second insulating layer which includes a convex portion while enclosing at least one end of the first insulating layer, a light emitting diode disposed on the convex portion of the second insulating layer, and a third insulating layer which includes a concave portion while enclosing an end of the first insulating layer or the second insulating layer, wherein the convex portion and the concave portion at least partially overlap.

According to an aspect of the present disclosure, there is provided a manufacturing method of a display apparatus. The manufacturing method of the display apparatus comprises forming a driving circuit unit and a power line on a first substrate, forming a planarization layer on the driving circuit unit and the power line, forming a first contact hole which exposes at least a part of a source electrode of the driving circuit unit and a second contact hole which exposes at least a part of the power line on the planarization layer, forming a metal layer connected to the source electrode and a connection line connected to the power line on the planarization layer, forming a first insulating layer and a second insulating layer on the metal layer and the connection line, disposing a light emitting diode on the second insulating layer, forming a contact hole which overlaps the second contact hole, a third contact hole which exposes at least a part of the metal layer, and a convex portion formed by an area which overlaps the light emitting diode on the first insulating layer and the second insulating layer, and forming a third insulating layer on the second insulating layer, wherein the third insulating layer includes a concave portion which overlaps the convex portion of the second insulating layer.

According to the present disclosure, a step of the contact hole is improved to suppress the short-circuit of the connection line.

According to the present disclosure, the short-circuit of the connection line is minimized to improve the reliability of the display apparatus.

According to the present disclosure, a step area of a light shielding layer is reduced or minimized to improve the reflectance of the display apparatus.

The effects according to the present disclosure are not limited to the contents exemplified above, and more various effects are included in the present specification.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other aspects, features and other advantages of the present disclosure will be more clearly understood from the following detailed description taken in conjunction with the accompanying drawings, in which:

FIG. 1 is a schematic diagram of a display apparatus according to an exemplary embodiment of the present disclosure;

FIG. 2A is a partial cross-sectional view of a display apparatus according to an exemplary embodiment of the present disclosure;

FIG. 2B is a perspective view of a tiling display apparatus according to an exemplary embodiment of the present disclosure;

FIG. 3 is a plan view of a display panel of a display apparatus according to an exemplary embodiment of the present disclosure;

FIGS. 4A to 4F are plan views illustrating a display apparatus manufacturing method and a structure of a pixel area of FIG. 3; and

FIGS. 5A to 5E are cross-sectional views illustrating a display apparatus manufacturing method and a structure of an area taken along the line A-A′ of FIG. 4F.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, dimensions, (e.g., sizes, lengths, widths, heights, thicknesses, locations, radii, diameters, and areas), ratios, angles, numbers, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The terms, such as “below,” “lower,” “above,” “upper” and the like, may be used herein to describe a relationship between element(s) as illustrated in the drawings. It will be understood that the terms are spatially relative and based on the orientation depicted in the drawings.

When an element or layer is disposed “on” another element or layer, another layer or another element may be interposed directly on the other element or therebetween.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Although the terms “first,” “second,” “A,” “B,” “(a),” and “(b),” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

Exemplary embodiments of the present disclosure may be independently carried out from each other or carried out to be associated with each other.

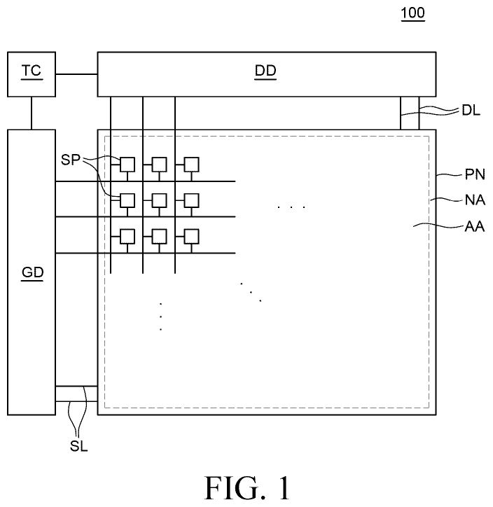

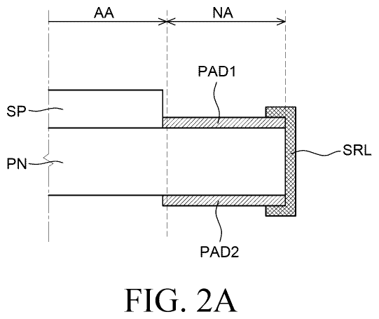

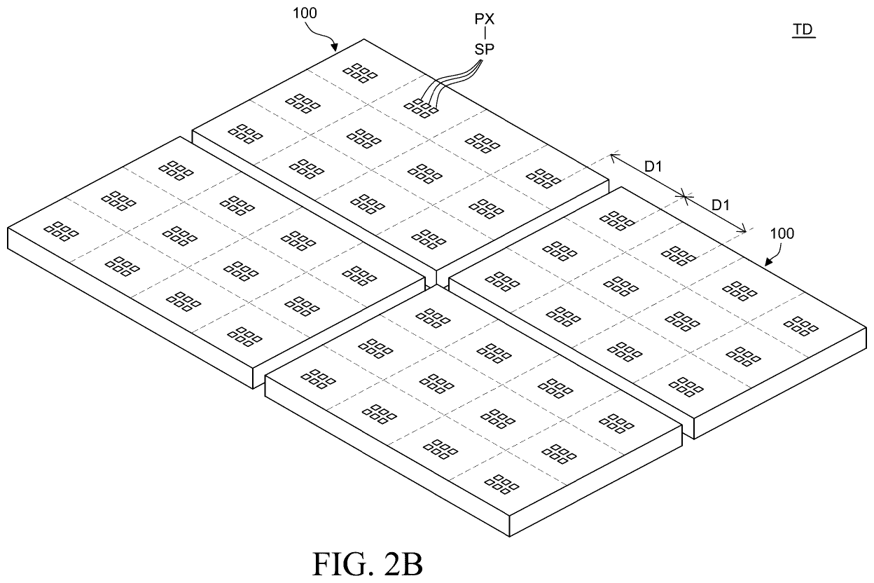

FIG. 1 is a schematic diagram of a display apparatus according to an exemplary embodiment of the present disclosure. FIG. 2A is a partial cross-sectional view of a display apparatus according to an exemplary embodiment of the present disclosure. FIG. 2B is a perspective view of a tiling display apparatus according to an exemplary embodiment of the present disclosure. In FIG. 1, for the convenience of description, among various components of the display apparatus, only a display panel PN, a gate driver GD, a data driver DD, and a timing controller TC are schematically illustrated.

Referring to FIG. 1, the display apparatus includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto. As an example, two gate drivers GD may be disposed at opposite sides of the display panel PN, without being limited thereto. As an example, two or more gate drivers GD may be disposed at one or more sides of the display panel PN, without being limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD. Although it is illustrated that the timing controller TC, the gate driver GD and the data driver DD are separate components, embodiments are not limited thereto. As an example, at least two of the timing controller TC, the gate driver GD and the data driver DD may be integrated as one component. As an example, one or more addition component may be further included.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA extending from the active area AA may be defined. As an example, the non-active area NA may partially or fully enclose the active area AA.

The active area AA is an area where images are displayed in the display apparatus. In the active area AA, a plurality of sub pixels SP which configures a plurality of pixels PX and a circuit unit for driving the plurality of sub pixels SP may be disposed. The sub pixel SP is a minimum unit which configures the active area AA and n sub pixels SP may form one pixel PX. In each of the plurality of sub pixels SP, a light emitting diode, a circuit unit for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED), without being limited thereto.

In the active area AA, a plurality of wiring lines which transmits various signals to the plurality of sub pixels SP is disposed. For example, the plurality of wiring lines may include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

However, the non-active area NA may be located on a rear surface of the display panel PN, that is, a surface on which the sub pixels SP are not disposed or may be omitted, and is not limited as illustrated in the drawing. As an example, the non-active area NA may be partially or fully bent toward a rear side of the display panel PN, so as to be partially or fully invisible from a front side of the display panel, without being limited thereto.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN. Embodiments are not limited thereto. As an example, the gate driver GD may be separately provided (for example, on a separate flexible film or printed circuit board), and then connected to the display panel DP in a tape automated bonding (TAB) method, a chip on glass (COG) method, a chip on panel (COP) method, or a chip on film (COF) method, without being limited thereto.

If the gate driver GD is mounted in the GIP (gate in panel) manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA (gate in active area) manner and a side line SRL which connects the signal line (or a pad electrode) on the front surface of the display panel PN to a pad electrode on a rear surface of the display panel PN is formed to bond the flexible film and the printed circuit board onto a rear surface of the display panel PN, the non-active area NA may be reduced or minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes for transmitting various signals to the plurality of sub pixels SP is disposed. For example, in the non-active area NA on the front surface of the display panel PN, a plurality of first pad electrodes PAD1 which transmits a signal to the plurality of sub pixels SP is disposed. In the non-active area NA on the rear surface of the display panel PN, a plurality of second pad electrode PAD2 which is electrically connected to a driving component, such as a flexible film and the printed circuit board, is disposed. That is, on the front surface of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to reduce or minimize an area of the non-active area NA on the front surface of the display panel PN.

Referring to FIG. 2B, a tiling display apparatus TD having a large screen size may be implemented by connecting a plurality of display apparatuses 100. At this time, as illustrated in FIG. 2A, when the tiling display apparatus TD is implemented using a display apparatus 100 with a reduced or minimized bezel, a seam area between the display apparatuses 100 in which an image is not displayed is reduced or minimized so that a display quality may be improved.

For example, a plurality of sub pixels SP may form one pixel PX and a first distance D1 between an outermost pixel PX of one display apparatus 100 and an outermost pixel PX of another display apparatus 100 adjacent to the one display apparatus may be implemented to be equal to a second distance D2 between pixels PX in the one display apparatus 100. Accordingly, distances D1 and D2 between pixels PX between the display apparatuses 100 are constantly configured to reduce or minimize the seam area.

However, FIGS. 2A and 2B are illustrative so that the display apparatus 100 according to the exemplary embodiment of the present disclosure may be a general display apparatus with a bezel, but is not limited thereto.

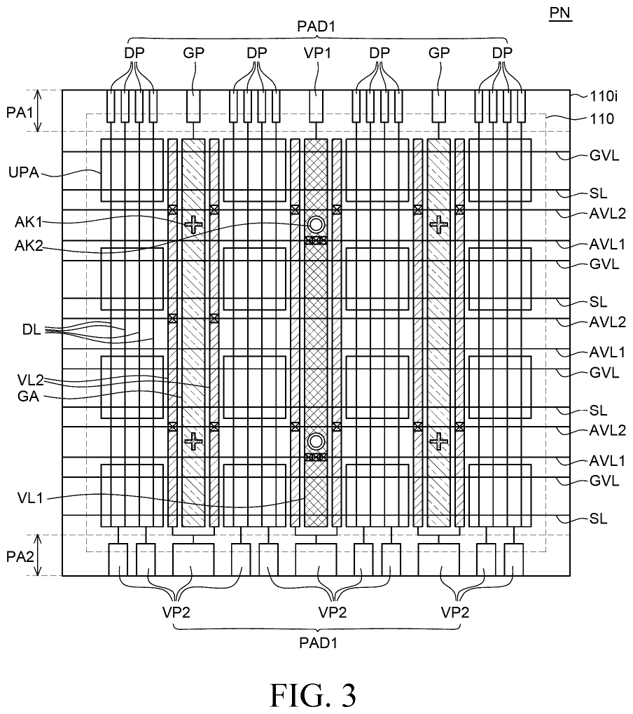

FIG. 3 is a plan view of a display panel of a display apparatus according to an exemplary embodiment of the present disclosure.

Referring to FIG. 3, in the display panel PN, a plurality of pixels PX is formed on a substrate (e.g., an insulating substrate) to display images. For example, the insulating substrate may be formed of glass or resin and may include polymer or plastic, without being limited thereto. Further, the insulating substrate may be formed of a plastic material having flexibility. Embodiments are not limited thereto. As an example, the substrate may be a rigid substrate or a flexible substrate. As an example, the insulating substrate may be formed of polyethylene terephthalate (PET), polycarbonate (PC), acrylonitrile-butadiene-styrene copolymer (ABS), polyimide (PI) film, etc., without being limited thereto.

In the insulating substrate, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed while forming a plurality of rows and a plurality of columns. Each of the plurality of pixels PX disposed in the plurality of pixel areas UPA includes a plurality of sub pixels SP. Each of the plurality of sub pixels SP includes a light emitting diode and a pixel circuit to (e.g., independently) emit light.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, the gate driver GD may include, for example, a plurality of transistors and/or capacitors. Here, active layers of the plurality of transistors may be formed of a semiconductor material, such as an oxide semiconductor, amorphous silicon, polysilicon, compound semiconductor, organic semiconductor, etc., but are not limited thereto. The active layers of the plurality of transistors may be formed of the same material or different materials from each other. Further, the active layers of the transistors of the gate driver may be formed of the same material as active layers of various transistors of the pixel circuit or formed of different materials from each other.

The plurality of pad areas is areas in which a plurality of first pad electrodes PAD1 is disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and/or a low potential power pad VP2, without being limited thereto. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas may include a first pad area PA1 and a second pad area PA2, or may include only one pad area or more than two pad areas. As an example, the plurality of pad areas may include a first pad area PA1 located at an upper edge of the display panel PN and a second pad area PA2 at a lower edge of the display panel PN, without being limited thereto. At this time, as an example, in the first pad area PA1 and the second pad area PA2, different types of first pad electrodes PAD1 may be disposed. For example, in the first pad area PA1, among the plurality of first pad electrodes PAD1, the data pad DP, the gate pad GP, and the high potential power pad VP1 may be disposed and in the second pad area PA2, the low potential power pad VP2 may be disposed. Embodiments are not limited thereto. As an example, same type of first pad electrodes PAD1 may be disposed in the first pad area PA1 and the second pad area PA2. As an example, each of the data pad DP, the gate pad GP, the high potential power pad VP1 and the low potential power pad VP2 may be disposed in one or both of the first pad area PA1 and the second pad area PA2, without being limited thereto.

At this time, as an example, the plurality of first pad electrodes PAD1 may be formed to have different sizes, respectively, without being limited thereto. For example, the plurality of data pads DP which is connected to the plurality of data lines DL (e.g., one to one) may have a smaller width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto. As an example, at least some or all of the data pad DP, the gate pad GP, the high potential power pad VP1, and the low potential power pad VP2 may have the same size.

In the meantime, in order to reduce the bezel of the display panel PN, as an example, an edge of the display panel PN may be cut to be removed, without being limited thereto. The plurality of pixels PX, the plurality of wiring lines, and the plurality of first pad electrodes PAD1 are formed on an initial first substrate 110i which is an insulating substrate and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL may extend from the plurality of data pads DP of the first pad area PA1 toward the plurality of pixel areas UPA. The plurality of data lines DL extends in a column direction and overlaps the plurality of pixel areas UPA. Therefore, the plurality of data lines DL may transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extends from the high potential power pad VP1 of the first pad area PA1 to the plurality of pixel areas UPA to transmit the high potential power voltage to the light emitting diodes of each of the plurality of sub pixels SP. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extends from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extends in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction is electrically connected to the plurality of high potential power lines VL1 extending in the column direction through a contact hole and may form a mesh structure. Therefore, the plurality of auxiliary high potential power lines AVL1 and the plurality of high potential power lines VL1 are configured to form a mesh structure to reduce or minimize voltage drop and voltage deviation.

A plurality of auxiliary low potential power lines AVL2 extending in the row direction is disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and reduce or minimize voltage deviation.

The plurality of auxiliary high potential power lines AVL1 and a plurality of auxiliary low potential power lines AVL2 may be additionally disposed between the plurality of data lines DL which extends in the column direction of the display panel PN.

The plurality of gate driving lines GVL extending in the row direction and the column direction is disposed on the first substrate 110 of the display panel PN. Some of the plurality of gate driving lines GVL extends from the gate pad GP of the first pad area PA1 to the gate driving area GA to transmit a signal to the gate driver GD. The other gate driving lines GVL of the plurality of gate driving lines GVL extend in the row direction and transmit the signal to the gate drivers GD of the plurality of gate driving areas GA. Therefore, various signals may be transmitted from the gate driving line GVL to the gate driver GD to drive the gate driver GD.

The plurality of gate driving lines GVL may include wiring lines which transmit a clock signal, a start signal, a gate high voltage, and a gate low voltage to the gate driver GD. Therefore, various signals are transmitted from the gate driving line GVL to the gate driver GD to drive the gate driver GD.

A plurality of alignment keys AK1 and AK2 is disposed in an area between the plurality of pixel areas UPA in the display panel PN. The plurality of alignment keys AK1 and AK2 is used for alignment during the manufacturing process of the display panel PN. The plurality of alignment keys AK1 and AK2 includes a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, as an example, a hole overlapping the second alignment key AK2 is formed to divide the second alignment key AK2 and the high potential power line VL1, without being limited thereto. The second alignment key AK2 may be used to align the display panel PN and a donor. The display panel PN and the donor are aligned using the second alignment key AK2 and the plurality of light emitting diodes 130 of the donor may be transferred onto the display panel PN. For example, the second alignment key AK2 may have a circular ring shape, but is not limited thereto. Embodiments are not limited thereto. As an example, the display panel PN may comprise only one of the first alignment key AK1 and the second alignment key AK2, or may comprise one or more additional alignment keys in addition to the first alignment key AK1 and the second alignment key AK2. As an example, the first alignment key AK1 and the second alignment key AK2 may be disposed at various positions, without being limited to that illustrated in FIG. 3.

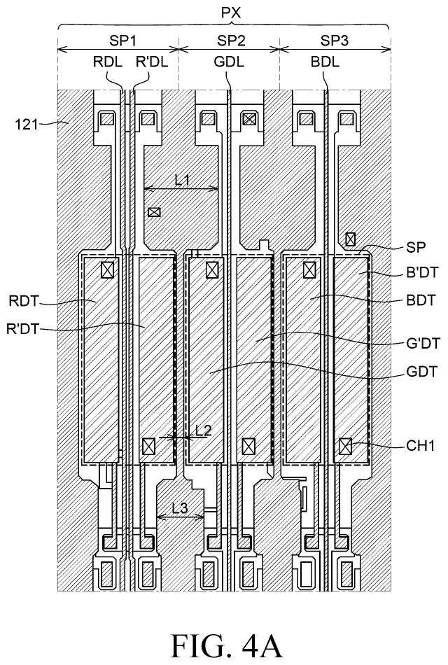

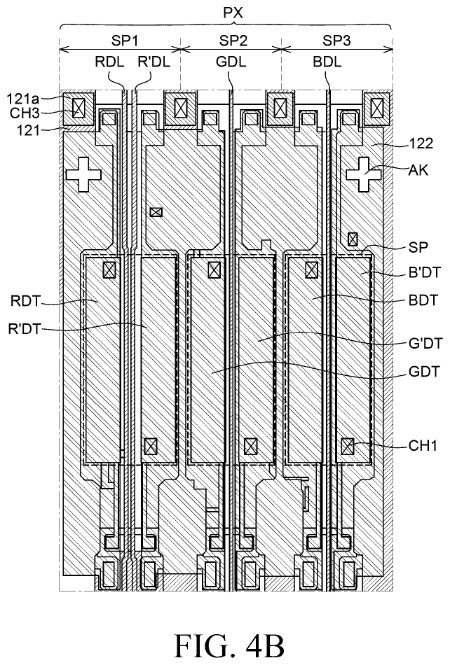

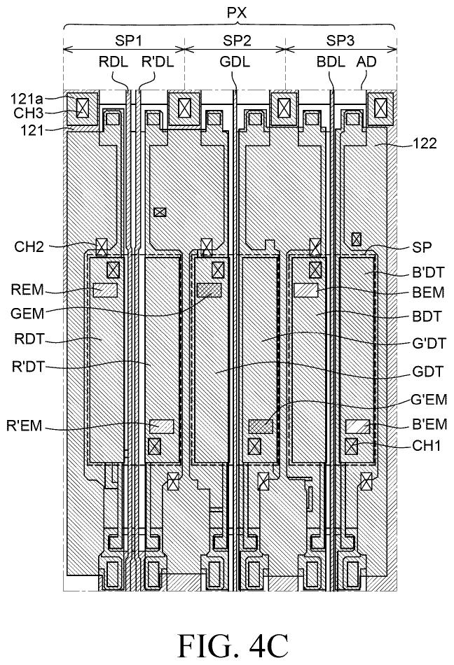

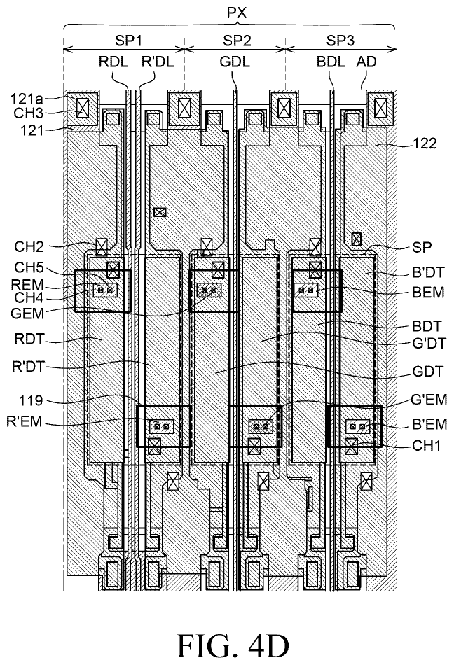

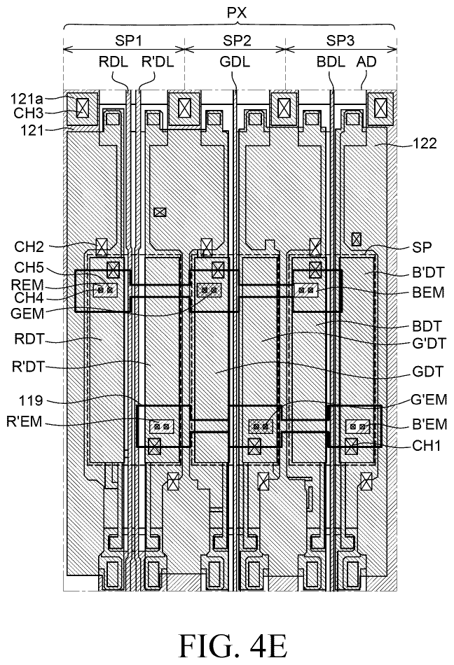

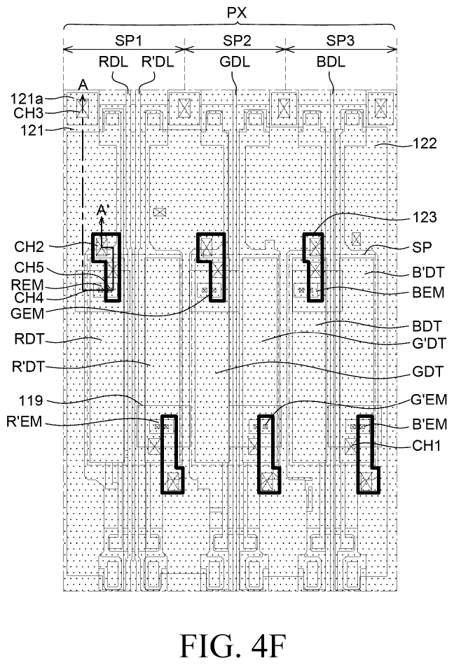

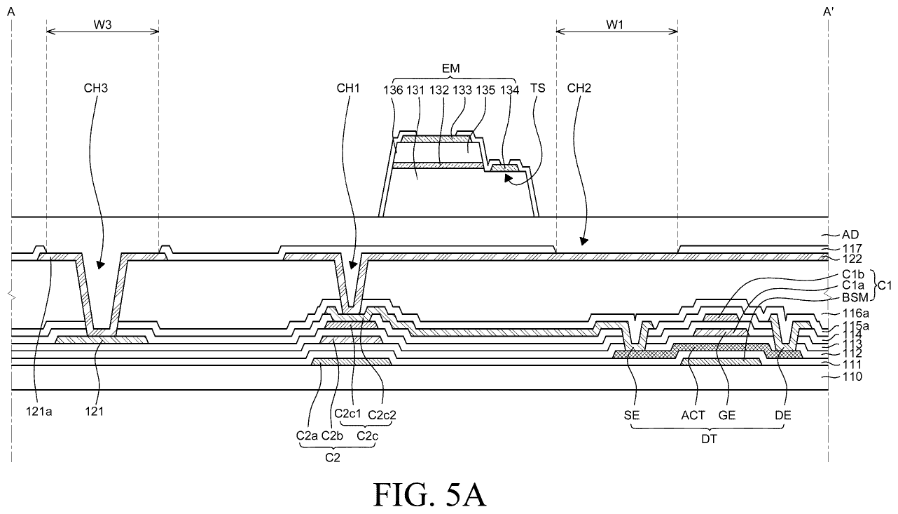

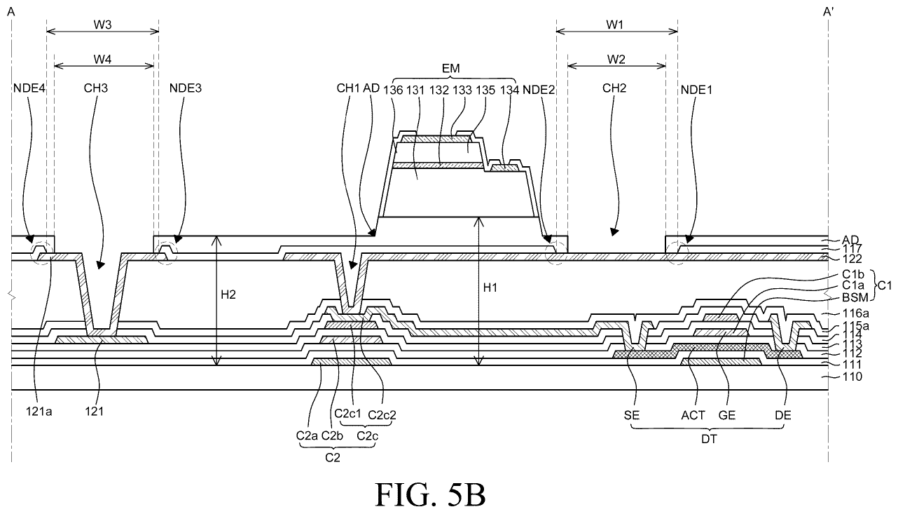

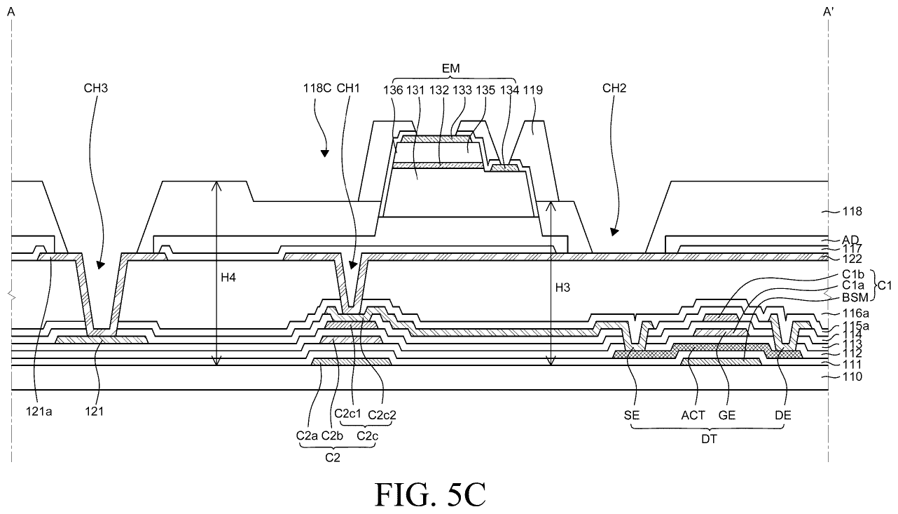

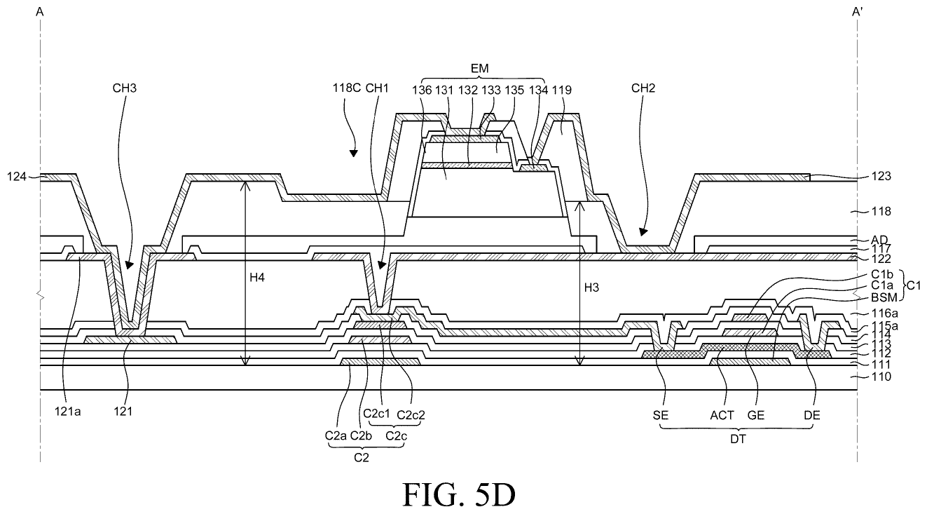

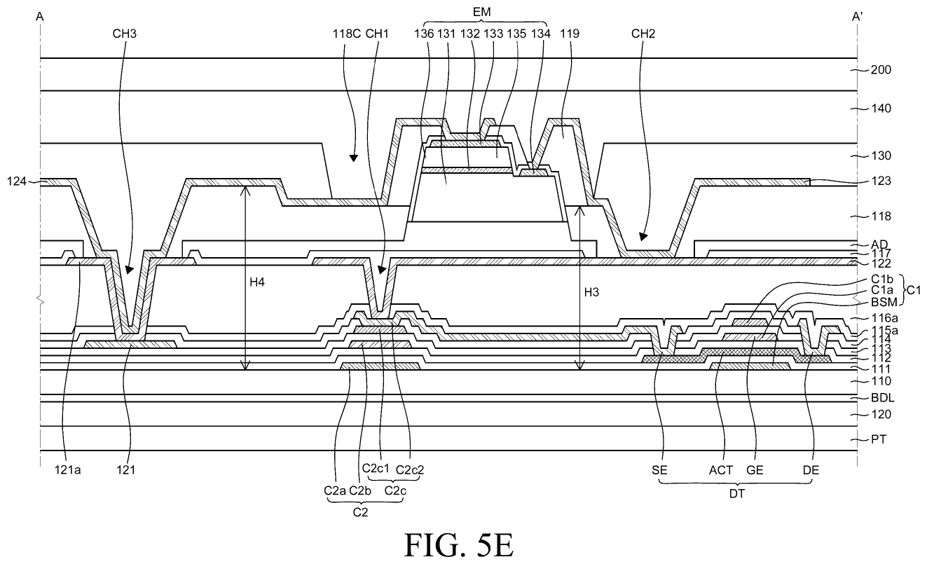

The pixel PX and the sub pixel SP of the pixel area UPA will be described in more detail with reference to FIGS. 4A to 4D and 5A to 5E.

The active area AA on the first substrate 110 may include an emission area and a non-emission area. The emission area is an area in which a light emitting diode is disposed to emit light and the non-emission area is an area in which a light emitting diode is not disposed.

The plurality of sub pixels SP which forms one pixel PX is disposed in one pixel area UPA. For example, the plurality of sub pixels SP may include a first sub pixel SP1, a second sub pixel SP2, and a third sub pixel SP3 which emit different color light. Embodiments are not limited thereto. As an example, the plurality of sub pixels SP which forms one pixel PX may include more than three sub pixels. As an example, the more than three sub pixels may emit different color light, or at least some of the more than three sub pixels may emit the same color light. As an example, one or more pixels PX may be disposed in one pixel area UPA.

As an example, a red light emitting diode may be disposed in the first sub pixel SP1, a green light emitting diode may be disposed in the second sub pixel SP2, and a blue light emitting diode may be disposed in the third sub pixel SP3, without being limited thereto. A sub pixel of a color (e.g., while, cyan, magenta, yellow, etc.) other than red, green and blue may be alternatively or additionally included.

Referring to FIG. 4A, as described above, wiring lines which supply various signals to the plurality of sub pixels SP1, SP2, and SP3 are disposed in the plurality of pixels PX of the first substrate 110. For example, a plurality of data lines RDL, R′DL, GDL, and BDL extending in the column direction and the power line 121 which transmits a signal of a low potential power pad VP2 (FIG. 3) or a high potential power pad VP1 (FIG. 3) may be disposed on the first substrate 110.

The power line 121 transmits a low potential or high potential power to each sub pixel SP and transmits a high potential or low potential power to the driving circuit unit to drive the light emitting diode.

The power line 121 may be disposed between the respective sub pixels SP and may be formed to be wider than the plurality of data lines RDL, R′DL, GDL, and BDL, without being limited thereto. As an example, the power line 121 may be formed as wide as possible to reduce or minimize the voltage drop and the voltage deviation of the power voltage, without being limited thereto.

Each sub pixel SP1, SP2, or SP3 may include a driving circuit unit and include at least two light emitting diodes, without being limited thereto.

In order to drive at least two light emitting diodes, the driving circuit unit of each sub pixel SP1, SP2, or SP3 may include main emission circuit units RDT, GDT, and BDT and auxiliary emission circuit units R′DT, G′DT, and B′DT.

In the red sub pixel SP1, a red main emission circuit unit RDT and a red auxiliary emission circuit unit R′DT include a first red data line RDL and a second red data line R′DL, respectively. The green sub pixel SP2 and the blue sub pixel SP3 apply signals to a green main emission circuit unit GDT and a green auxiliary emission circuit unit G′DT and a blue main emission circuit unit BDT and a blue auxiliary emission circuit unit B′DT through one green data line GDL and one blue data line BDL. Embodiments are not limited thereto. As an example, the red main emission circuit unit RDT and the red auxiliary emission circuit unit R′DT may include one red data line RDL, while the green main emission circuit unit GDT and the green auxiliary emission circuit unit G′DT or the blue main emission circuit unit BDT and the blue auxiliary emission circuit unit B′DT may include one data line, without being limited thereto.

The driving circuit unit may include a first contact hole CH1 (or more than one contact holes) for electrically connecting the light emitting diode and the transistor of the driving circuit unit.

As an example, the power line 121 has a width which varies for every area to be disposed as wide as possible in an area excluding an area in which the driving circuit unit is disposed and a contact area to which the driving circuit unit and lower wiring lines are connected.

The power line 121 includes a first area and a second area and a width L1 of the first area and a width L2 of the second area are different. As an example, the width L1 of the first area is larger than the width L2 of the second area.

Further, the power line 121 further includes a third area and a width L3 of the third area may be larger than the width L2 of the second area and may be smaller than the width L1 of the first area.

As an example, the power line 121 (e.g., a low potential power line) may be formed by the same process as the plurality of data lines RDL, R′DL, GDL, and BDL, or may be formed by a different process from the plurality of data lines RDL, R′DL, GDL, and BDL.

The power line 121 and the plurality of data lines RDL, R′DL, GDL, and BDL may be formed of the same or different conductive materials. As an example, the power line 121 and the plurality of data lines RDL, R′DL, GDL, and BDL may be formed of one or more of opaque metal materials, such as copper (Cu), aluminum (Al), molybdenum (Mo), nickel (Ni), titanium (Ti), and chrome (Cr), or an alloy thereof, but are not limited thereto.

Further, a light shielding layer BSM, a semiconductor layer ACT, and/or insulating layers may be disposed below the power line 121 and the plurality of data lines RDL, R′DL, GDL, and BDL.

Referring to FIG. 4B, a metal layer 122 may be disposed on the driving circuit unit and the power line 121. At this time, as an example, the metal layer 122 may be electrically connected to the driving circuit unit through the first contact hole CH1. A first connection electrode 121a is disposed on the power line 121 to transmit a signal of the power line 121 to the light emitting diode through a third contact hole CH3.

The metal layer 122 overlaps electrodes of the driving circuit unit to form a capacitor. The metal layer 122 may have a width overlapping the entire driving circuit unit to ensure a sufficient capacitor.

The metal layer 122 may include a reflective material to reflect light of the light emitting diode to be upwardly emitted. As an example, the metal layer 122 and the first connection electrode 121a may include one or more of copper (Cu), aluminum (Al), molybdenum (Mo), nickel (Ni), titanium (Ti), chrome (Cr), and indium tin oxide (ITO), or an alloy thereof, but are not limited thereto. As an example, the metal layer 122 and the first connection electrode 121a may include the same material or different materials.

The alignment key may be formed by etching a part of the metal layer 122. The alignment key AK may be disposed in an area in which the power line 121 and the metal layer 122 overlap, but is not limited thereto.

Referring to FIG. 4C, an adhesive layer AD may be disposed on the metal layer 122, the first connection electrode 121a, and the substrate 110. The adhesive layer AD may include a second contact hole CH2 which exposes a part of the metal layer 122 to electrically connect the light emitting diode and the metal layer 122 and a third contact hole CH3 which exposes a part of the first connection electrode 121a to electrically connect the light emitting diode and the power line 121.

Light emitting diodes REM, R′EM, GEM, G′EM, BEM, and B′EM may be disposed on the adhesive layer AD of each sub pixel.

Referring to FIGS. 4D and 4E, a third planarization layer 119 which covers a top and a side surface of the light emitting diodes REM, R′EM, GEM, G′EM, BEM, B′EM is disposed.

The third planarization layer 119 is disposed on the top and the side surface of the light emitting diodes REM, R′EM, GEM, G′EM, BEM, and B′EM with a larger size than the light emitting diodes REM, R′EM, GEM, G′EM, BEM, and B′EM. A fourth contact hole CH4 and a fifth contact hole CH5 are formed above the light emitting diodes REM, R′EM, GEM, G′EM, BEM, and B′EM to expose a part of a first electrode layer 134 and a second electrode layer 135 of the light emitting diodes REM, R′EM, GEM, G′EM, BEM, and B′EM.

The third planarization layer 119 is spaced apart from the second contact hole CH2 and the third contact hole CH3 disposed therearound to suppress depths of the second contact hole CH2 and the third contact hole CH3 from becoming deeper as much as a height of the third planarization layer 119.

In FIG. 4E, a third planarization layer 119 according to another exemplary embodiment of the present disclosure is disposed. The third planarization layer 119 may be disposed to enclose the light emitting diodes REM, R′EM, GEM, G′EM, BEM, and B′EM to fix each light emitting diode REM, R′EM, GEM, G′EM, BEM, and B′EM to the substrate 110. At this time, the third planarization layer is not individually disposed to enclose each of the light emitting diodes REM, R′EM, GEM, G′EM, BEM, and B′EM, but may be disposed to enclose two or more of the light emitting diodes REM, R′EM, GEM, G′EM, BEM, and B′EM, e.g., the light emitting diodes REM, R′EM, GEM, G′EM, BEM, and B′EM of a row or column direction in the pixel PX. In this case, the third planarization layer may be disposed between two or more light emitting diodes so that a fixing strength to fix the light emitting diodes REM, R′EM, GEM, G′EM, BEM, and B′EM to the substrate may be improved.

Referring to FIG. 4F, a first electrode 123 and a second electrode 124 may be disposed on the substrate 110. The first electrode 123 may electrically connect driving circuit units RDT, GDT, BDT, R′DT, G′DT, and B′DT of each of the sub pixels SP1, SP2, and SP3 and the second electrode layers 135 of the light emitting diodes REM, R′EM, GEM, G′EM, BEM, and B′EM.

The second electrode 124 may be disposed on the entire substrate 110 excluding an area in which the first electrode 123 is disposed and may electrically connect the power line 121 and the light emitting diodes REM, R′EM, GEM, G′EM, BEM, and B′EM, without being limited thereto.

As an example, the first electrode 123 and the second electrode 124 may be formed on the same layer by the same process and are spaced apart from each other with a predetermined interval. Embodiments are not limited thereto. As an example, the first electrode 123 and the second electrode 124 may be formed on different layers and/or by different processes. As an example, the first electrode 123 even overlap a portion of the second electrode 124.

FIGS. 5A to 5E are cross-sectional views illustrating a display apparatus manufacturing method and a structure of an area taken along the line A-A′ of FIG. 4F.

The display panel PN includes a first substrate 110. The first substrate 110 is a substrate which supports components disposed above the display panel PN and may be, for example, an insulating substrate, without being limited thereto. A plurality of pixels PX is formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility, without being limited thereto.

The light shielding layer BSM may be disposed on the first substrate 110. The light shielding layer BSM blocks light which is incident to active layers ACT of the plurality of transistors to reduce or minimize a leakage current. For example, the light shielding layer BSM is disposed below the active layer ACT of the driving transistor DT to block light incident onto the active layer ACT.

If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque material (e.g., an opaque conductive material) such as copper (Cu), aluminum (Al), molybdenum (Mo), nickel (Ni), titanium (Ti), chrome (Cr), or an alloy thereof, but is not limited thereto. As an example, the light shielding layer BSM may be configured by an opaque insulating material, without being limited thereto. As an example, the light shielding layer BSM may be omitted depending on the design.

A buffer layer 111 is disposed on the light shielding layer BSM. The buffer layer 111 may reduce permeation of moisture or impurities through the first substrate 110. For example, the buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of the thin film transistor, but is not limited thereto.

Even though it is not illustrated, an additional buffer layer may be disposed between the first substrate 110 and the light shielding layer BSM. The additional buffer layer may be configured by a single layer or a double layer of silicon oxide (SiOx) or silicon nitride (SiNx) to reduce permeation of moisture or impurities through the first substrate 110, like the buffer layer 111.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material, such as an oxide semiconductor, amorphous silicon, polysilicon, compound semiconductor, or organic semiconductor, but is not limited thereto. Further, even though it is not illustrated in the drawings, other transistors, such as a switching transistor, a sensing transistor, and an emission control transistor, other than the driving transistor DT, may be further disposed. The active layers of the transistors may also be formed of a semiconductor material, such as an oxide semiconductor, amorphous silicon, polysilicon, compound semiconductor, or organic semiconductor, but are not limited thereto. The active layer of the transistor included in the pixel circuit, such as the driving transistor DT, the switching transistor, the sensing transistor, and the emission control transistor, may be formed of the same material, or formed of different materials.

A gate insulating layer 112 is disposed on the active layer ACT. The gate insulating layer 112 is an insulating layer which electrically insulates the active layer ACT from the gate electrode GE and may be configured by a single layer, a double layer, or a multiple layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT, respectively, are formed. The first interlayer insulating layer 113 and the second interlayer insulating layer 114 are insulating layers which protect components therebelow and may be configured by single layers, double layers or multiple layers of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE is connected to the second capacitor C2 and the first electrode 123 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The power line 121 may be formed on the second interlayer insulating layer 114 with the same material by the same process as the source electrode SE and the drain electrode DE, without being limited thereto. As an example, the power line 121 may be disposed on a layer different from the second interlayer insulating layer 114 (e.g., the buffer layer 111, the gate insulating layer 112 or the first interlayer insulating layer 113, etc.). As an example, the power line 121 may be formed of a different material from the source electrode SE and the drain electrode DE and/or may be formed by a different process from the source electrode SE and the drain electrode DE, without being limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT, or may be separately formed with the gate electrode GE of the driving transistor DT.

The 1-2-th capacitor electrode C1b is disposed on the first interlayer insulating layer 113. The 1-2-th capacitor electrode C1b is disposed so as to overlap the 1-1-th capacitor electrode C1a with the first interlayer insulating layer 113 therebetween. Embodiments are not limited thereto. As an example, the 1-2-th capacitor electrode C1b may be disposed on the second interlayer insulating layer 114, without being limited thereto. As an example, the first capacitor C1 may be disposed on the first interlayer insulating layer 113, and may be connected to the gate electrode GE of the driving transistor DT, without being limited thereto.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. As an example, the second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode. Embodiments are not limited thereto. As an example, the second capacitor C2 may include only two capacitor electrodes. As an example, the second capacitor C2 may include two of the 2-1-th capacitor electrode C2a, the 2-2-th capacitor electrode C2b and the 2-3-th capacitor electrode C2c, without being limited thereto.

As an example, the 2-1-th capacitor electrode C2a may be disposed on the first substrate 110. As an example, the 2-1-th capacitor electrode C2a may be disposed on the same layer as the light shielding layer BSM and may be formed of the same material as the light shielding layer BSM, without being limited thereto.

As an example, the 2-2-th capacitor electrode C2b may be disposed on the buffer layer 111 and the gate insulating layer 112. As an example, the 2-2-th capacitor electrode C2b may be disposed on the same layer as the gate electrode GE and may be formed of the same material as the gate electrode GE, without being limited thereto.

As an example, the 2-3-th capacitor electrode C2c may be disposed on the first interlayer insulating layer 113. As an example, the 2-3-th capacitor electrode C2c may be configured by a first layer C2c1 and a second layer C2c2, without being limited thereto. As an example, a first layer C2c1 of the 2-3-th capacitor electrode C2c may be formed on the same layer with the same material as the 1-2-th capacitor electrode C1b, without being limited thereto. The first layer C2c1 may be disposed so as to overlap the 2-1-th capacitor electrode C2a and the 2-2-th capacitor electrode C2b with the first interlayer insulating layer 113 therebetween.

The second layer C2c2 of the 2-3-th capacitor electrode C2c may be disposed on the second interlayer insulating layer 114. The second layer C2c2 may be a part extending from the source electrode SE of the driving transistor DT and may be connected to the first layer C2c1 through a contact hole of the second interlayer insulating layer 114, without being limited thereto.

Accordingly, the second capacitor C2 is electrically connected to the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, the second capacitor C2, and the power line 121. The first passivation layer 115a is an insulating layer which protects components below the first passivation layer 115a and may be configured by an inorganic material, such as silicon oxide (SiOx) or silicon nitride (SiNx), but is not limited thereto.

A first planarization layer 116a is disposed on the first passivation layer 115a. The first planarization layer 116a may planarize an upper portion of the pixel circuit including the driving transistor DT. The first planarization layer 116a may be configured by a single layer, a double layer or a multiple layer, and for example, configured by benzocyclobutene or an acrylic organic material, but is not limited thereto.

The first contact hole CH1 and the third contact hole CH3 may be formed in the first passivation layer 115a and the first planarization layer 116a.

The first contact hole CH1 may expose a part of the electrode SE of the driving transistor DT or a part of the 2-3-th capacitor electrode C2c of the second capacitor C2.

The third contact hole CH3 may expose a part of the power line 121.

As an example, the metal layer 122 and the first connection electrode 121a may be disposed on the first planarization layer 116a.

A plurality of metal layers 122 may be disposed to be spaced apart from each other in a predetermined area.

The metal layer 122 may electrically connects the light emitting diode LED to a power line VDD and the driving transistor DT. As an example, the metal layer 122 may serve as a reflector which reflects light emitted from the light emitting diode to the top of the light emitting diode, without being limited thereto. As an example, the plurality of metal layer 122 may be formed of a conductive material having an excellent reflective property to reflect light emitted from the light emitting diodes to the top of the light emitting diode, without being limited thereto. As an example, at least some of the plurality of metal layer 122 may be formed of a conductive material having poor reflective property.

The metal layer 122 may electrically connect the driving transistor DT and the light emitting diode EM. The metal layer 122 may be connected to the source electrode SE or the drain electrode DE of the driving transistor DT through the first contact hole CH1 formed in the first planarization layer 116a. The metal layer 122 may be electrically connected to an electrode and a semiconductor layer of the light emitting diode LED through the first electrode 123 to be described below.

The first connection electrode 121a is partially spaced apart from the metal layer 122 to be formed in an area of the third contact hole CH3 through which the power line 121 and the light emitting diode EM are electrically connected. Therefore, the resistance may be reduced in the electrical connection of the power line 121 and the light emitting diode EM.

The first connection electrode 121a may electrically connect the power line 121 to a p-type electrode 134 and a p-type semiconductor layer 131 of the light emitting diode EM through the second electrode 124 to be described below.

The passivation layer 117 is disposed on the metal layer 122 and the first connection electrode 121a. In the passivation layer 117, a second contact hole CH2 for connecting the first electrode 123 to the metal layer 122 and a third contact hole CH3 for connecting the second electrode 124 to the light emitting diode EM are formed. The passivation layer 117 is an insulating layer which protects components below the passivation layer 117 and may be configured by a single layer, a double layer or a multiple layer of silicon oxide (SiOx) or silicon nitride (SiNx), but is not limited thereto.

The third contact hole CH3 is formed on the passivation layer 117 and the first planarization layer 116a to connect the second electrode 124 and the power line 121. A hole formed in the first planarization layer 116a may be formed to have a smaller width than a hole formed in the passivation layer 117 to form a stepped shape, without being limited thereto.

The adhesive layer AD is disposed on the passivation layer 117 and the first planarization layer 116a. The adhesive layer AD is coated on the entire substrate 110 to fix the light emitting diode EM disposed on the adhesive layer AD. The adhesive layer AD may be selected from any one of adhesive polymer, epoxy resist, UV resin, polyimide, acrylate, urethane, and polydimethylsiloxane (PDMS), but is not limited thereto. A material which configures the adhesive layer AD as described above is an insulating material so that the adhesive layer may be referred to as an insulating layer.

The plurality of light emitting diodes EM is disposed in each of the plurality of sub pixels SP on the adhesive layer AD. The light emitting diode EM is an element which emits light by a current and the plurality of light emitting diodes EM may include a light emitting diode EM which emits red light, green light, and blue light and implement various colored light including white by a combination thereof. For example, the plurality of light emitting diodes EM may be a light emitting diode (LED) or a micro LED, but is not limited thereto.

The light emitting diode EM includes a first n-type semiconductor layer 133, a first emission layer 132, a first p-type semiconductor layer 131, a first n-type electrode 135, a first p-type electrode 134, and a first encapsulation film 136.

The first n-type semiconductor layer 133 is disposed on the adhesive layer AD and the first p-type semiconductor layer 134 is disposed on the first n-type semiconductor layer 133. The first n-type semiconductor layer 133 and the first p-type semiconductor layer 134 may be formed by doping n-type and p-type impurities into a specific material. For example, the first n-type semiconductor layer 133 and the first p-type semiconductor layer 134 may be layers doped with n-type and p-type impurities into a material such as gallium nitride (GaN), indium aluminum phosphide (InAlP), or gallium arsenide (GaAs), without being limited thereto. The p-type impurity may be magnesium (Mg), zinc (Zn), beryllium (Be), and the like, and the n-type impurity may be silicon (Si), germanium, tin (Sn), and the like, but is not limited thereto.

The first emission layer 132 is disposed between the first n-type semiconductor layer 133 and the first p-type semiconductor layer 134. The first emission layer 132 is supplied with holes and electrons from the first n-type semiconductor layer 133 and the first p-type semiconductor layer 134 to emit light. The first emission layer 132 may be formed with a single layer or a multi-quantum well (MQW) structure, and for example, may be formed of indium gallium nitride (InGaN) or gallium nitride (GaN), but is not limited thereto.

Referring to FIG. 5A, the first emission layer 132 and the first p-type semiconductor layer 131 are disposed to be spaced apart from the first n-type electrode 133. The first n-type electrode 133 is spaced apart from the first emission layer 132 and the first p-type semiconductor layer 131 to be disposed on one side or both sides of the first emission layer 132 and the first p-type semiconductor layer 131, but is not limited thereto.

At least one or more first n-type electrodes 135 are disposed on the first n-type semiconductor layer 133. The first n-type electrode 135 is an electrode which electrically connects the driving transistor DT and the first n-type semiconductor layer 133. The first n-type electrode 135 may be disposed on a top surface of the first n-type semiconductor layer 133 which is exposed from the first emission layer 132 and the first p-type semiconductor layer 131. For example, the first n-type electrode 135 may be disposed to be adjacent to an end portion or both end portions of a top surface TS of the first n-type semiconductor layer 133, for example, having a circular planar shape from a plan view, without being limited thereto. A planar shape of the first n-type electrode 135 may be a circular and/or oval shape, or an angular shape, from a plan view, without being limited thereto. The first n-type electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first p-type electrode 134 is disposed on the first p-type semiconductor layer 131. The first p-type electrode 134 may be disposed on the top surface of the first p-type semiconductor layer 131. A planar shape of the first p-type electrode 134 may be a circular and/or oval shape, or an angular shape, without being limited thereto. The first p-type electrode 134 is an electrode which electrically connects the power line 121 and the first p-type semiconductor layer 131. The first p-type electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the first encapsulation film 136 which encloses the first n-type semiconductor layer 133, the first emission layer 132, the first p-type semiconductor layer 131, the first n-type electrode 135, and the first p-type electrode 134 is disposed. The first encapsulation film 136 is formed of an insulating material to protect the first n-type semiconductor layer 133, the first emission layer 132, and the first p-type semiconductor layer 131. In the first encapsulation film 136, a contact hole which exposes the first n-type electrode 135 and the first p-type electrode 134 is formed to electrically connect the first electrode 123 and the second electrode 124 to the first n-type electrode 135 and the first p-type electrode 134, respectively.

Referring to FIG. 5B, the adhesive layer AD may be removed from areas of the second contact hole CH2 and the third contact hole CH3, for example, through an exposure process to form a hole.

As an example, the second contact hole CH2 and the third contact hole CH3 of the adhesive layer AD are formed to be narrower than the second contact hole CH2 and the third contact hole CH3 formed in the passivation layer 117 so that the adhesive layer AD covers an end (e.g., NDE1, NDE2, NDE3, and NDE4) of the passivation layer 117. For example, the second contact hole CH2 formed in the passivation layer 117 has a width W1 as shown in FIG. 5A. After a portion of the adhesive layer AD is removed (thereby exposing the top surface of the metal layer 122), the hole in the adhesive layer AD now has a narrower width W2 than width W1. Here, a first end NDE1 and a second end NDE2 of the passivation layer 117 is covered by the adhesive layer AD. Similarly, the third contact hole CH3 formed in the passivation layer 117 has a width W3 as shown in FIG. 5A. After a portion of the adhesive layer AD is removed (thereby exposing the top surface of the metal layer 122), the hole in the adhesive layer AD now has a narrower width W4 than width W3. Here, a third end NDE3 and a fourth end NDE4 of the passivation layer 117 is covered by the adhesive layer AD.

When the second contact hole CH2 and the third contact hole CH3 of the adhesive layer AD are formed to be wider than the second contact hole CH2 and the third contact hole CH3 formed in the passivation layer 117, widths of the second contact hole CH2 and the third contact hole CH3 formed in the second passivation layer 118 to be described later are increased on the adhesive layer AD. Therefore, an area required for the hole in the panel PN may be increased.

The adhesive layer AD is coated on the substrate 110 to dispose the light emitting diode EM and then photoresist is coated and the exposure process is performed with photo equipment, and then the hole may be formed, for example, by a dry etching process, without being limited thereto.

When the exposure process is performed, the adhesive layer AD is cured so that the adhesive strength is lowered, so that a process of forming a hole may be performed after placing and bonding the light emitting diode EM.

After the dry etching, an ashing process of removing foreign materials on the photoresist and the adhesive layer AD with oxygen plasma is performed. When the ashing process is performed, an area in which the adhesive layer AD is exposed is partially etched so that a level of an adhesive layer AD of an area which does not overlap the light emitting diode EM is lower than that of an area which overlaps the light emitting diode EM. Therefore, a convex portion may be included in an area which overlaps the light emitting diode EM.

The adhesive layer AD which overlaps the light emitting diode EM may have a first height H1 from a top surface of the substrate 110 to a top surface of the adhesive layer AD. The adhesive layer AD of the area which does not overlap the emission layer 132 may have a second height H2 from the top surface of the substrate 110 to the top surface of the adhesive layer AD. The first height H1 may be larger than the second height H2.

The second planarization layer 118 may be disposed on the adhesive layer AD. The second planarization layer 118 may be disposed on the adhesive layer AD while enclosing a side surface of the light emitting diode EM.

The adhesive layer AD is subject to the dry etching and an end may have a reverse taper or a right-angle shape. When the first electrode 123 and the second electrode 124 to be described below are disposed at the end of the adhesive layer AD, the first electrode 123 and the second electrode 124 may be broken due to the shape of the end of the adhesive layer AD while forming the first electrode 123 and the second electrode 124.

In order to suppress this, the second planarization layer 118 covers the end of the adhesive layer AD in the area of the second contact hole CH2 and the third contact hole CH3 to form the second contact hole CH2 and the third contact hole CH3.

The second contact hole CH2 may be formed by the passivation layer 117, the adhesive layer AD, and the second planarization layer 118 and the third contact hole CH3 may be formed by the first planarization layer 116a, the passivation layer 117, the adhesive layer AD, and the second planarization layer 118.

The second planarization layer 118 may include a third height H3 and a fourth height H4. The third height H3 is a height from the top surface of the substrate 110 to the top surface of the second planarization layer 118 in an area adjacent to the light emitting diode EM. The fourth height H4 is a height from the top surface of the substrate 110 to the top surface of the second planarization layer 118 in an area which is spaced apart from the light emitting diode EM with a predetermined interval.

The third height H3 and the fourth height H4 are different and the fourth height H4 is higher than the third height H3 so that the second planarization layer 118 may include a concave unit in an area where the light emitting diode EM is disposed.

An area 118c of the concave portion of the second planarization layer 118 may overlap an area of the convex portion of the adhesive layer AD.

The height of the second planarization layer 118 has a step so that the third planarization layer 119 to be described later may be disposed in an area of the third height H3 in which the light emitting diode EM is disposed.

The second planarization layer 118 and the third planarization layer 119 may be configured by a single layer or a double layer, and for example, configured by benzocyclobutene or an acrylic organic material, but are not limited thereto.

The third planarization layer 119 is disposed so as to enclose a top and a side surface of the light emitting diode EM to fix the light emitting diode EM to the substrate 110.

Referring to FIGS. 4D, 4E, and 5C, the third planarization layer 119 encloses only the light emitting diode EM, but does not overlap the second contact hole CH2 and the third contact hole CH3.

A height of the third planarization layer 119 may be formed to be sufficiently high (for example, approximately 3 um to 10 um, without being limited thereto) to cover the top surface of the light emitting diode EM.

When the third planarization layer 119 is disposed in the area of the second contact hole CH2 and the third contact hole CH3, depths of the second contact hole CH2 and the third contact hole CH3 may be increased by a height of the third planarization layer 119.

The larger the depths of the second contact hole CH2 and the third contact hole CH3, the higher and the taper of the contact hole due to the adhesive layer AD, the second planarization layer 118, and the third planarization layer 119. Therefore, a connection stability of the first electrode 123 and the second electrode 124 with the metal layer 122 and the power line 121 therebelow may be lowered.

The third planarization layer 119 may be disposed with an island shape which encloses each light emitting diode EM or may be disposed so as to enclose one or more light emitting diodes EM, but is not limited thereto.

The third planarization layer 119 may include an opening which partially exposes the first n-type electrode 135 and the first p-type electrode 134 of the light emitting diode EM and may be partially disposed between the first n-type electrode 135 and the first p-type electrode 134 above the light emitting diode EM.

The first electrode 123 and the second electrode 124 may be disposed on the third planarization layer 119.

The first electrode 123 connects the first n-type electrode 135 of the light emitting diode EM and the metal layer 122 to transmit a high potential power signal from the driving transistor DT to the light emitting diode EM.

The second electrode 124 connects the power line 121 to the first p-type electrode 134 of the light emitting diode EM through the first connection electrode 121a to transmit a low potential power signal to the light emitting diode EM.

The first electrode 123 and the second electrode 124 may be formed by the same process and may be formed of the same material (e.g., a transparent conductive material), without being limited thereto. For example, the first electrode 123 and the second electrode 124 may be formed of indium tin oxide (ITO) or indium zinc oxide (IZO), but are not limited thereto. As an example, the first electrode 123 and the second electrode 124 may be formed by different processes and/or may be formed of different materials.

When the first n-type electrode 135 of the light emitting diode EM is connected to the first electrode 123 and the driving circuit unit and the first p-type electrode 134 is connected to the driving circuit unit, the power line 121 which is connected to the second electrode 124 may transmit the high potential voltage to the light emitting diode EM and the driving circuit unit may transmit the low potential voltage to the light emitting diode EM.

Referring to FIG. 5E, a black matrix 130 may be disposed on the first electrode 123 and the second electrode 124.

The black matrix 130 is spaced apart from the light emitting diode EM with a predetermined interval to be disposed on the entire substrate 110 excluding the emission area. This structure may suppress the deterioration of the transistors of the driving circuit unit due to an externa light source.

The black matrix 130 may upwardly reflect light emitted from a side surface of the light emitting diode EM or may suppress the color mixture with light emitting diodes of another sub pixel, and define an emission area of the sub pixel SP.

The black matrix 130 may be disposed to be lower than the top surface of the third planarization layer 119 on the top surface of the substrate. The black matrix 130 may be formed in the second contact hole CH2 and the third contact hole CH3 and may be formed to have a uniform thickness on the second contact hole CH2 and the third contact hole CH3 so that the change in the reflectance of the external light due to the thickness of the black matrix 130 may be reduced.

The black matrix 130 may be formed of an opaque material and for example, may be formed of black resin, but is not limited thereto.

The first protection layer 140 is disposed on the entire black matrix 130 and the entire substrate 110. The first protection layer 140 is a layer for protecting components below the first protection layer 140, and for example, may be configured by a single layer, a double layer, or a multiple layer of translucent epoxy, silicon oxide (SiOx) or silicon nitride (SiNx), but is not limited thereto.

A cover substrate 200 for protecting individual layers and elements may be disposed on the first protection layer 140. The cover substrate may be configured with a structure of a single layer or multiple layers with a material such as organic or polyimide, polyethylene terephthalate, polyethylene naphthalate, polycarbonate, polyethersulfone, polyarylate, polysulfone, or cyclic-olefin copolymer, but is not limited thereto.

A touch electrode for touch operation may be additionally disposed on the first protection layer 140. The touch electrode may be electrically connected to the driving circuit unit and/or may be electrically connected to a touch driving circuit IC at the outside of the active area AA. As an example, the touch electrode may be omitted depending on the design.

A color filter may be further disposed in an area which overlaps the emission area on the first protection layer 140 and/or an optical film may be further disposed. The optical film may be a functional film which implements a higher quality image while protecting the display panel PN. For example, the optical film may include an anti-scattering film, an anti-glare film, an anti-reflecting film, a low-reflecting film, an OLED transmittance controllable film, or a polarizer, but is not limited thereto. As an example, the color filter and/or the optical film may be omitted depending on the design.

An adhesive layer may be additionally disposed between the optical film and the first protection layer 140.

A second substrate 120 may be further disposed below the first substrate 110. The second substrate 120 is a substrate which supports components disposed below the display panel PN and may be an insulating substrate. For example, the second substrate 120 may be formed of glass or resin. Further, the second substrate 120 may include polymer or plastic. The second substrate 120 may be formed of the same material as the first substrate 110, or may be formed of a different material from the first substrate 110. In some exemplary embodiments, the second substrate 120 may be formed of a plastic material having flexibility. The second substrate 120 may be omitted depending on the design.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area therebetween.

Referring to FIG. 2A, a plurality of second pad electrodes PAD2 is disposed on a rear surface of the second substrate 120. The plurality of second pad electrodes PAD2 is electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side line SRL which covers the end portion of the second substrate 120.

A side insulating layer which covers the plurality of side lines SRL may be additionally disposed. The side insulating layer may be formed on the top surface of the first substrate 110, the side surface of the first substrate 110, the side surface of the second substrate 120, and the rear surface of the second substrate 120 to cover the side line SRL.

In the meantime, when the plurality of side lines SRL is formed of a metal material, there may be a problem in that external light is reflected from the plurality of side lines SRL or light emitted from the light emitting diode EM is reflected from the plurality of side lines SRL to be visibly recognized by the user. Therefore, the side insulating layer may be configured to include a black material to suppress reflection of the external light, without being limited thereto. For example, the side insulating layer may be formed by a pad printing method using an insulating material including a black material, for example, a black ink.

Even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

A plate for supporting the display panel PN may be disposed on the rear surface of the second substrate 120 and below the driving component.

The exemplary embodiments of the present disclosure can also be described as follows:

According to an aspect of the present disclosure, there is provided a display apparatus. The display apparatus may comprises a substrate, a driving circuit unit disposed on the substrate in an active area, a first insulating layer disposed on the driving circuit unit, a second insulating layer which includes a convex portion while enclosing at least one end of the first insulating layer, a light emitting diode disposed on the convex portion of the second insulating layer, and a third insulating layer which includes a concave portion while enclosing an end of the first insulating layer or the second insulating layer, wherein the convex portion and the concave portion at least partially overlap.

The display apparatus may further comprise a power line which applies a power voltage to the light emitting diode, and a planarization layer disposed on the power line, wherein at least one or more of the first insulating layer, the second insulating layer, or the third insulating layer is disposed on the planarization layer.

The first contact hole may be formed in the planarization layer and the first insulating layer, the second insulating layer, or the third insulating layer.

The display apparatus may further comprise a connection line which electrically connects the light emitting diode and the driving circuit unit on the planarization layer.

The first contact hole may expose at least a part of the connection line.

The third insulating layer may enclose one end of the second insulating layer.

The display apparatus may further comprise a fourth insulating layer disposed in the concave portion of the third insulating layer, wherein the fourth insulating layer encloses at least a part of a side surface and a top surface of the light emitting diode.

The display apparatus may further comprise a light shielding layer disposed on the third insulating layer.

A first height from the top surface of the substrate to a top surface of the light shielding layer may be higher than a second height from a top surface of the substrate to a top surface of the fourth insulating layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate;
a driving circuit unit on the substrate in an active area;
a first insulating layer disposed over the driving circuit unit;
a light emitting diode on the first insulating layer; and
a second insulating layer enclosing an end of the first insulating layer,
wherein the light emitting diode is on the first insulating layer.

2. The display apparatus according to claim 1, further comprising:
a power line which is configured to apply a power voltage to the light emitting diode; and
a planarization layer on the power line,
wherein the first insulating layer and the second insulating layer are on the planarization layer.

3. The display apparatus according to claim 2, wherein a first contact hole is formed in the planarization layer.

4. The display apparatus according to claim 3, further comprising:
a connection line which electrically connects the light emitting diode and the driving circuit unit through the first contact hole, and is on the planarization layer.

5. The display apparatus according to claim 4, wherein the first contact hole exposes at least a part of an electrode of the driving circuit unit.

6. The display apparatus according to claim 2, wherein a first contact hole is formed in the planarization layer, the first insulating layer, and the second insulating layer, to expose a part of the power line.

7. The display apparatus according to claim 6, wherein an end of the second insulating layer adjacent to the first contact hole encloses an end of the first insulating layer adjacent to the first contact hole.

8. The display apparatus according to claim 7, further comprising:
a first electrode electrically connecting the power line to the light emitting diode through the first contact hole,
wherein the first electrode extends across the end of the second insulating layer adjacent to the first contact hole.

9. The display apparatus according to claim 7, wherein the end of the first insulating layer adjacent to the first contact hole has a reverse taper or a right-angle shape.

10. The display apparatus according to claim 2, further comprising:
a connection line which electrically connects the light emitting diode and the driving circuit unit on the planarization layer,
wherein a first contact hole is formed in the first insulating layer and the second insulating layer, to expose the connection line.

11. The display apparatus according to claim 10, wherein an end of the second insulating layer adjacent to the first contact hole encloses an end of the first insulating layer adjacent to the first contact hole.

12. The display apparatus according to claim 1, further comprising:
a third insulating layer on the second insulating layer,
wherein the third insulating layer encloses a side surface and at least a part of a top surface of the light emitting diode.

13. The display apparatus according to claim 12, further comprising:
a light shielding layer on the second insulating layer.

14. The display apparatus according to claim 13, wherein a first height from the top surface of the substrate to a top surface of the light shielding layer is lower than a second height from a top surface of the substrate to a top surface of the third insulating layer.

15. The display apparatus according to claim 13, wherein a first contact hole is formed in the first insulating layer and the second insulating layer, and the light shielding layer is formed in the first contact hole and has a uniform thickness on the first contact hole.

16. The display apparatus according to claim 1, wherein the first insulating layer includes a convex portion on which the light emitting diode is disposed.

17. The display apparatus according to claim 16, wherein the second insulating layer includes a concave portion overlapping the convex portion.

18. The display apparatus according to claim 16, wherein the second insulating layer covers a side surface of the convex portion and an interface between the convex portion and the light emitting diode.

19. The display apparatus according to claim 1, further comprising:
a third insulating layer disposed under the first insulating layer,
wherein the first insulating layer and the second insulating layer cover an end of the third insulating layer.
